(19) United States
(12) Patent Application Publication
(10) Pub. No.: US 2024/0229222 A9
(43) Pub. Date: Jul. 11, 2024

(54) EVAPORATION MATERIAL DISTRIBUTOR AND VACUUM EVAPORATION DEVICE

(71) Applicant: CHONGQING JIMAT NEW MATERIAL TECHNOLOGY CO., LTD., Chongqing (CN)

(72) Inventor: Shiwei ZANG, Chongqing (CN)

(73) Assignee: CHONGQING JIMAT NEW MATERIAL TECHNOLOGY CO., LTD., Chongqing (CN)

(21) Appl. No.: 18/401,723

(22) Filed: Jan. 2, 2024

Related U.S. Application Data
(63) Continuation of application No. PCT/CN2023/075621, filed on Feb. 13, 2023.

(30) Foreign Application Priority Data
Sep. 8, 2022 (CN) 202211093350.8

(51) Int. Cl. C23C 14/24

(52) U.S. Cl. CPC C23C 14/24

(57) ABSTRACT

An evaporation material distributor and a vacuum evaporation device are provided. The evaporation material distributor includes a material distribution mechanism and a housing, where the material distribution mechanism is provided at a bottom of the housing, and the material distribution mechanism includes a plurality of through holes formed in a middle of a bottom of the material distribution mechanism at intervals along a length direction of the material distribution mechanism; and a plurality of feeding channels respectively provided between the holes and corresponding edges of the material distribution mechanism.

### CROSS REFERENCE TO THE RELATED APPLICATIONS

This application is a continuation application of International Application No. PCT/CN2023/075621, filed on Feb. 13, 2023, which is based upon and claims priority to Chinese Patent Application No. 202211093350.8, filed on Sep. 8, 2022, the entire contents of which are incorporated herein by reference.

### TECHNICAL FIELD

The present disclosure relates to the technical field of vacuum evaporation, and in particular to an evaporation material distributor and a vacuum evaporation device.

### BACKGROUND

Vacuum evaporation involves placing a to-be-evaporated material into a crucible under vacuum conditions and then heating the crucible. The existing vacuum evaporation applications concern a plurality of crucibles that are subjected to evaporation together. The to-be-evaporated material is placed into the crucibles one by one, resulting in low efficiency. Moreover, it is difficult to place an equal amount of the to-be-evaporated material into each crucible, causing nonuniformity of the material evaporated to a thin film, thereby affecting product quality.

### SUMMARY

### (I) Technical Problem to be Solved

In view of defects and shortages of the prior art, the present disclosure provides an evaporation material distributor, to solve the technical problem that when a to-be-evaporated material is placed into crucibles, it is hard to place an equal to-be-evaporated material into each crucible to cause nonuniformity of the material evaporated to a thin film.

### (II) Technical Solutions

To achieve the above objective, the present disclosure adopts the following main technical solutions:

According to an aspect, the present disclosure provides an evaporation material distributor. The evaporation material distributor includes a material distribution mechanism and a housing, where the material distribution mechanism is provided at a bottom of the housing, and the material distribution mechanism includes a plurality of through holes formed inside the material distribution mechanism at intervals along a length direction of the material distribution mechanism; and a plurality of feeding channels respectively provided at two sides of the material distribution mechanism, and corresponding to the holes, each of the feeding channels communicating with a corresponding one of the holes.

Optionally, the plurality of through holes are formed in a middle of the material distribution mechanism in two rows.

Optionally, the material distribution mechanism further includes a plurality of guide tubes respectively provided at bottoms of the holes.

Optionally, the material distribution mechanism further includes a plurality of locating tubes; the locating tubes are respectively sleeved on inner sidewalls of the guide tubes; the locating tube is longer than the guide tube; and the locating tube includes one end connected to the hole, and the other end communicating with a crucible.

Optionally, gaps are respectively provided at tangents between the plurality of through holes and the plurality of feeding channels; the material distributor further includes a barrier, the barrier includes a top plate and barrier plates, the barrier plates are vertically connected to the top plate, and the barrier plates are respectively inserted into the gaps; and a width of the barrier plate is the same as a depth of the feeding channel.

Optionally, a handle is provided on the top plate.

Optionally, the material distribution mechanism further includes a slider provided in the feeding channel; a hollow locating rod threadedly connected to a sidewall of the material distribution mechanism through a bolt, and corresponding to the feeding channel; and an adjusting threaded rod fixedly connected to the slider through the hollow locating rod.

Optionally, the material distribution mechanism further includes a baffle plate provided on the feeding channel; and an edge of a side of the baffle plate close to the hole is fixedly connected to the slider.

Optionally, the housing is trumpet-shaped.

According to another aspect, the present disclosure further provides a vacuum evaporation device, including the above-mentioned evaporation material distributor.

### (III) Beneficial Effects

The present disclosure has following beneficial effects:

The evaporation material distributor provided by the present disclosure includes a material distribution mechanism and a housing. The material distribution mechanism is provided at a bottom of the housing. The material distribution mechanism includes a plurality of through holes formed in a middle of a bottom of the material distribution mechanism along a length direction of the material distribution mechanism, and a plurality of feeding channels respectively provided between the holes and corresponding edges of the material distribution mechanism. Compared with the prior art, the evaporation material distributor can uniformly place a to-be-evaporated material into each crucible through the plurality of channel and the plurality of through holes.

### BRIEF DESCRIPTION OF THE DRAWINGS

FIG. 1 is an overall schematic structural view of an evaporation material distributor according to a specific implementation of the present disclosure;

FIG. 2 is an overall schematic structural view of another evaporation material distributor according to a specific implementation of the present disclosure;

FIG. 3 is a right view of an evaporation material distributor according to a specific implementation of the present disclosure;

FIG. 4 is a bottom view of an evaporation material distributor according to a specific implementation of the present disclosure;

FIG. 5 is a schematic structural view of a guide tube and a locating tube according to a specific implementation of the present disclosure;

FIG. 6 is an overall schematic structural view of a barrier according to a specific implementation of the present disclosure;

FIG. 7 is a top view of an evaporation material distributor according to a specific implementation of the present disclosure;

FIG. 8 is a perspective view of an evaporation material distributor according to a specific implementation of the present disclosure;

FIG. 9 is a front view of an evaporation material distributor according to a specific implementation of the present disclosure;

FIG. 10 is a partially enlarged view of an evaporation material distributor according to a specific implementation of the present disclosure; and

FIG. 11 is a schematic structural view of a connection between a baffle plate and a slider according to a specific implementation of the present disclosure.

### REFERENCE NUMERALS

1: material distribution mechanism, 10: hole, 11: feeding channel, 12: guide tube, 13: locating tube, 14: gap, 15: slider, 16: hollow locating rod, 17: bolt, 18: adjusting threaded rod, and 19: baffle plate;

2: housing; and

3: barrier, 31: top plate, 32: barrier plate, and 33: handle.

### DETAILED DESCRIPTION OF THE EMBODIMENTS

In order to facilitate a better understanding of the above technical solutions, the exemplary embodiments of the present disclosure are described in more detail below with reference to the accompanying drawings. Although the accompanying drawings show exemplary embodiments of the present disclosure, it should be understood that the present disclosure may be implemented in various forms and should not be limited to the embodiments set forth herein. The embodiments are provided for a more thorough understanding of the present disclosure, so as to make the scope of the present disclosure be fully conveyed to those skilled in the art.

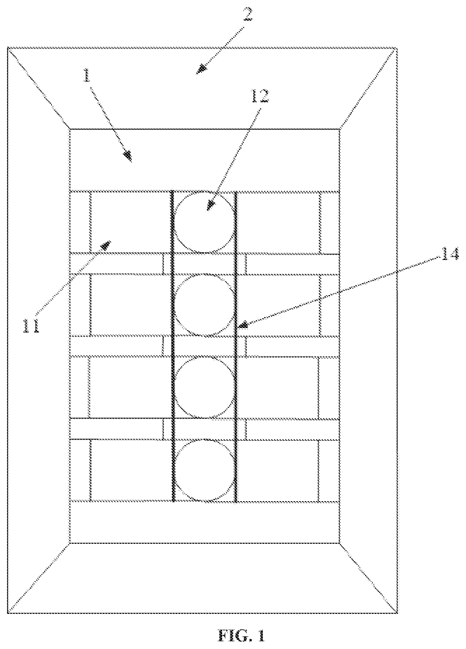

As shown in FIG. 1, a specific implementation of the present disclosure provides an evaporation material distributor, including material distribution mechanism 1 and housing 2. The material distribution mechanism 1 is provided at a bottom of the housing 2. The material distribution mechanism 1 includes a plurality of through holes 10 and a plurality of feeding channels 11. The plurality of through holes 10 are formed in a middle of the material distribution mechanism 1 at intervals along a length direction of the material distribution mechanism 1. The plurality of feeding channels 11 are respectively located at two sides of the material distribution mechanism 1, and corresponding to the through holes 10. Each of the feeding channels 11 communicates with a corresponding one of the holes 10. In the embodiment, one row of the holes 10 are formed in the middle of the material distribution mechanism 1, and the feeding channels 11 are respectively located at two sides of the row of the holes 10. Each hole 10 corresponds to two feeding channels 11. A to-be-evaporated material is placed into the feeding channels 11 first, and then enters the plurality of holes 10 through the feeding channels 11. Through the plurality of through holes 10, the to-be-evaporated material is placed into crucibles. In the embodiment, each hole 10 corresponds to two feeding channels 11, such that the to-be-evaporated material can be distributed quickly and uniformly. It is to be noted that a number of the holes 10 can be set according to a number of the crucibles.

The evaporation material distributor provided by the present disclosure can place the to-be-evaporated material into the crucibles uniformly at the same time, such that the material evaporated to a thin film is uniform. This can improve a production efficiency and a product quality.

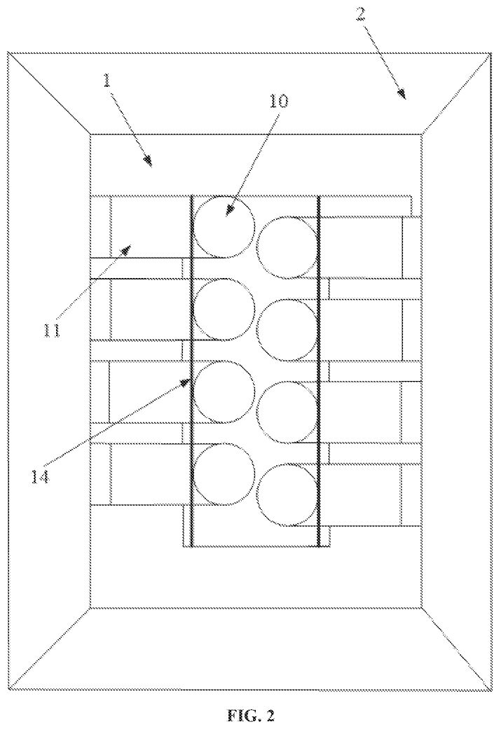

As shown in FIG. 2, in some embodiments, the plurality of through holes 10 may be formed in the middle of the material distribution mechanism 1 in two rows. Between each row of the holes 10 and a corresponding edge of the material distribution mechanism 1, the feeding channels 11 are provided correspondingly. In addition, the plurality of through holes 10 can be provided in one row or two rows according to a number of the crucibles and a size of the material distribution mechanism 1, such as a length and a width of the material distribution mechanism 1. For example, in response to a greater length and a smaller width of the material distribution mechanism 1, the plurality of through holes 10 can be provided in one row. In this case, the feeding channels 11 are respectively provided between the one row of the holes 10 and edges at two sides of the material distribution mechanism 1, namely each hole 10 corresponds to two feeding channels 11. In response to a smaller length and a greater width of the material distribution mechanism 1, the plurality of through holes 10 can be provided in two rows. In this case, the feeding channels 11 are respectively provided between each row of the holes 10 and a corresponding edge at one side of the material distribution mechanism 1, namely each hole 10 corresponds to one feeding channel 11. In the embodiment of the present disclosure, positions of the holes 10 can be provided flexibly according to the size of the material distribution mechanism 1.

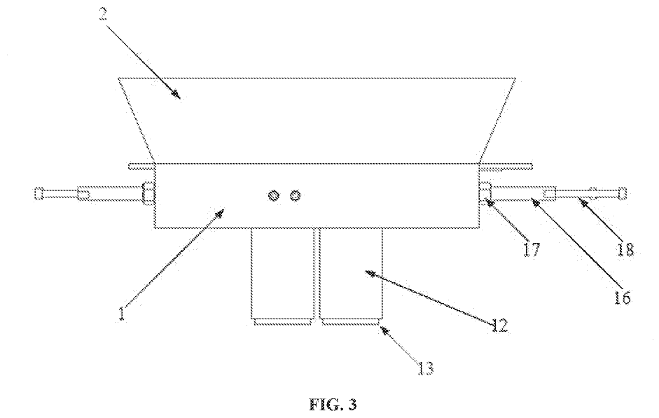

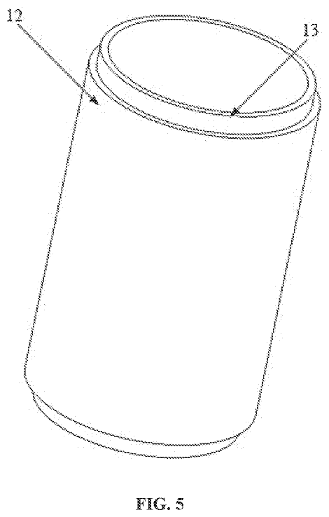

As shown in FIG. 3 to FIG. 5, in some embodiments, the material distribution mechanism 1 further includes a plurality of guide tubes 12 respectively provided at bottoms of the holes 10. In the embodiment, the to-be-evaporated material is guided to the crucible through the guide tube 12. Usually, the crucible is circular. Through the circular guide tube 12, the to-be-evaporated material is completely guided to each crucible. This prevents the to-be-evaporated material from splashing to the outside to cause nonuniformity of the to-be-evaporated material in each crucible.

As shown in FIG. 3 to FIG. 5, in some embodiments, the material distribution mechanism 1 further includes a plurality of locating tubes 13. The locating tubes 13 are respectively sleeved on inner sidewalls of the guide tubes 12. The locating tube 13 is longer than the guide tube 12. The locating tube 13 includes one end connected to the hole 10, and the other end connected to a crucible. That is, the guide tube 12 is fixed under the hole 10 through the locating tube 13. With the locating tube 13, the guide tube 12 can be in one-to-one correspondence with the crucible. The locating tube 13 is sleeved on the inner sidewall of the guide tube 12, and the locating tube 13 is longer than the guide tube 12, such that protrusive steps are provided at two ends of a whole portion formed by the guide tube 12 and the locating tube 13. The extended step portion includes one end connected to the crucible, and the other end connected to the hole 10 of the material distribution mechanism 1. In the embodiment of the present disclosure, the guide tube 12 is located through the locating tube 13. The guide tube can be directly located to the crucible. This can guide the to-be-evaporated material to the crucible more conveniently.

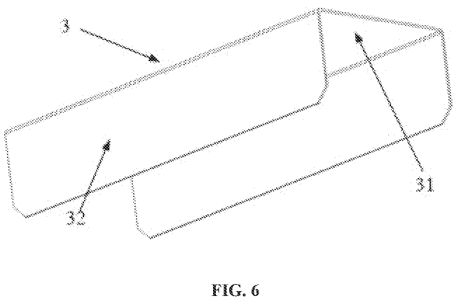

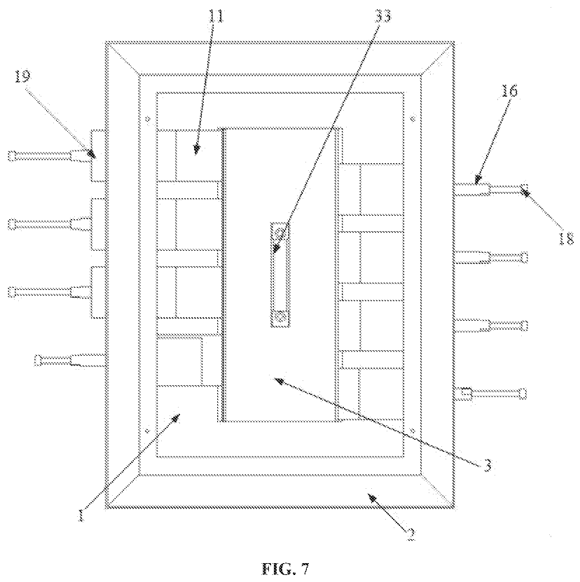

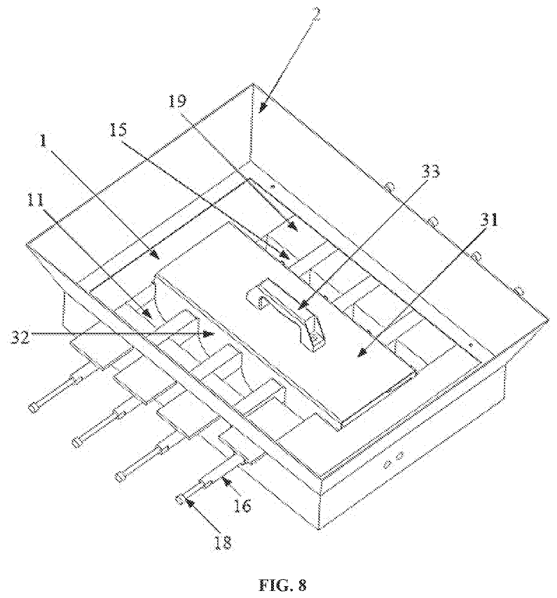

As shown in FIG. 1, FIG. 2, FIG. 6, FIG. 7 and FIG. 8, in some embodiments, gaps 14 are provided at tangents between the plurality of through holes 10 and the plurality of feeding channels 11. That is, the gaps 14 are provided at junctions between the plurality of through holes 10 and the plurality of feeding channels 11 and at tangents of the plurality of through holes 10. The material distributor further includes barrier 3. The barrier 3 includes top plate 31 and barrier plates 32. The barrier plates 32 are vertically connected to the top plate 31. The barrier plates 32 are respectively inserted into the gaps 14. A width of the barrier plate 32 is the same as a depth of the feeding channel 11 to fittingly separate the feeding channel 11 and the hole 10. In the embodiment of the present disclosure, with the barrier 3 for separating the hole 10 and the feeding channel 11, the to-be-evaporated material does not fall into the crucible through the hole 10 in advance in material distribution to cause non-uniform material distribution. Optionally, handle 33 may further be provided on the top plate 31, so as to place and take out the barrier 3 conveniently. Optionally, a chamfer may be provided at a bottom of each of left and right sides of the barrier plate 32. A chamfer may also be provided at an edge of the corresponding gap 14. The chamfer ranges from 30° to 60°. In this way, the barrier plate 32 can be inserted into the gap 14 more conveniently.

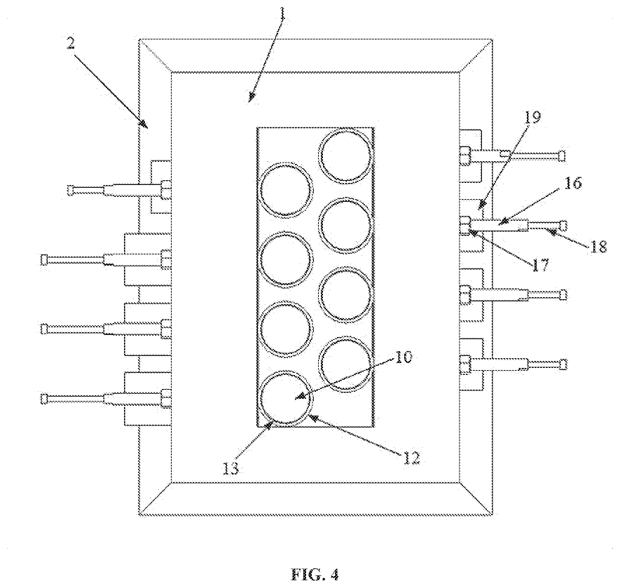

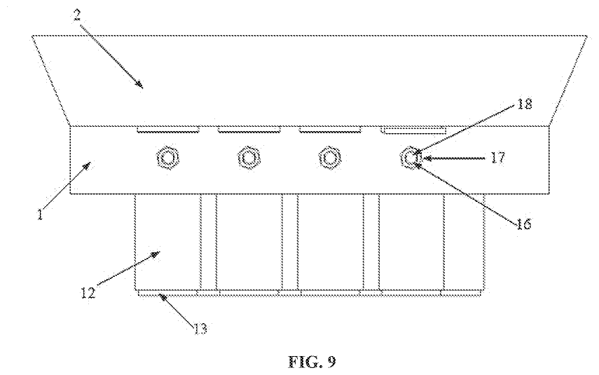

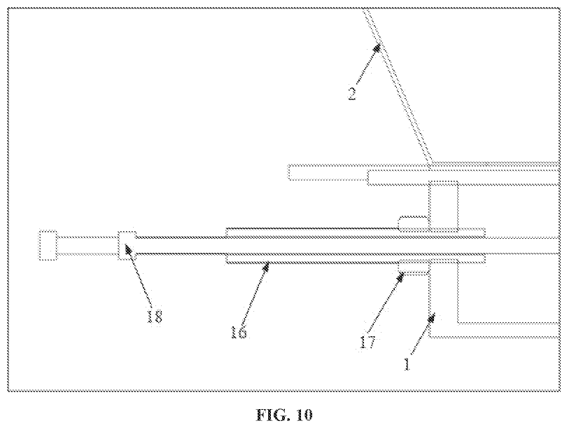

As shown in FIG. 3, FIG. 4, FIG. 7, FIG. 8, FIG. 9 and FIG. 10, in some embodiments, the material distribution mechanism 1 further includes slider 15, hollow locating rod 16, bolt 17, and adjusting threaded rod 18. The slider 15 is provided in the feeding channel 11. The hollow locating rod 16 is threadedly connected to a sidewall of the material distribution mechanism 1 through the bolt 17, and corresponds to the feeding channel 11. The adjusting threaded rod 18 is fixedly connected to the slider 15 through the hollow locating rod 16. In the embodiment of the present disclosure, the slider 15 is pulled and pushed through the adjusting threaded rod 18. When the slider is pulled, the to-be-evaporated material is placed into the feeding channel 11. The to-be-evaporated material is pushed into the hole 10 by pushing the slider 15 and then guided to the crucible through the guide tube 12. In addition, by rotating the hollow locating rod 16, a length of the hollow locating rod 16 penetrated into the feeding channel 11 can be adjusted. The slider 15 is located through the hollow locating rod 16, such that the slider 15 in the feeding channel 11 is located at a same position to quantify the to-be-evaporated material.

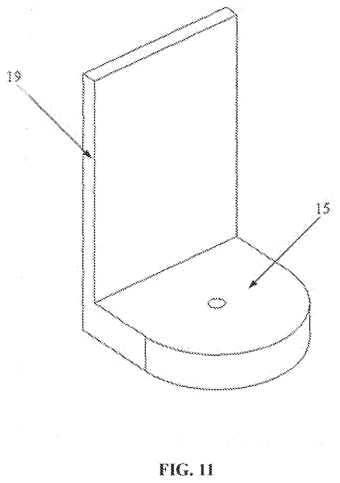

As shown in FIG. 4, FIG. 7, FIG. 8 and FIG. 11, in some embodiments, the material distribution mechanism 1 further includes baffle plate 19. The baffle plate 19 is provided on the feeding channel 11. An edge of a side of the baffle plate 19 close to the hole 10 is fixedly connected to the slider 15. Specifically, the slider 15 is shorter than the feeding channel 11. The slider 15 divides the feeding channel 11 into a side close to the hole 10 and a side away from the hole 10. The baffle plate 19 shields the feeding channel 11 at the side away from the hole 10. In this way, the to-be-evaporated material falls completely into the feeding channel 11 at the side close to the hole 10, thereby entering the crucible through the hole 10. In the embodiment of the present disclosure, the baffle plate 19 shields the feeding channel 11 between the slider 15 and the edge of the material distribution mechanism 1. In the material distribution, this prevents the to-be-evaporated material (copper particles or aluminum particles) from falling into the feeding channel 11 between the slider 15 and the edge of the material distribution mechanism 1.

In some embodiments, the housing 2 may be trumpet-shaped. This can prevent the to-be-evaporated material from scattering to the ground in the material distribution to waste the material and cause environmental pollution.

The present disclosure further provides a vacuum evaporation device. The vacuum evaporation device includes any evaporation material distributor described above. With the evaporation material distributor for material distribution, not only is a thin-film evaporation efficiency improved, but also the to-be-evaporated material can be uniformly placed into each crucible to improve a thin-film evaporation quality.

The evaporation material distributor provided by the present disclosure has a following working principle:

The barrier 3 covers the plurality of through holes 10 in the material distribution mechanism 1, and separates the holes 10 and the feeding channels 11. The slider 15 is pulled to the hollow locating rod 16 through the adjusting threaded rod 18, thereby locating the slider 15. The to-be-evaporated material (such as copper particles or aluminum particles) is placed into the feeding channel 11. The barrier 3 is lifted by the handle 33. The slider 15 is pushed through the adjusting threaded rod 18, thereby pushing the to-be-evaporated material in the feeding channel 11 into the hole 10. The to-be-evaporated material is guided to the crucible through the guide tube 12 and the locating tube 13, thereby realizing uniform distribution of the material.

The present disclosure has the following beneficial effects:

The evaporation material distributor provided by the present disclosure can place the to-be-evaporated material into the crucibles uniformly at the same time, such that the material evaporated to a thin film is uniform. This can improve a production efficiency and a product quality.

According to the evaporation material distributor provided by the present disclosure, positions of the holes 10 can be provided flexibly according to the size of the material distribution mechanism 1.

According to the evaporation material distributor provided by the present disclosure, the to-be-evaporated material is guided to the crucible through the guide tube 12. Usually, the crucible is circular. Through the circular guide tube 12, the to-be-evaporated material is completely guided to each crucible. This prevents the to-be-evaporated material from splashing to the outside to cause nonuniformity of the to-be-evaporated material in each crucible.

According to the evaporation material distributor provided by the present disclosure, the guide tube 12 is located through the locating tube 13. The guide tube can be directly located to the crucible. This can guide the to-be-evaporated material to the crucible more conveniently.

According to the specific implementation of the present disclosure, with the barrier 3 for separating the hole 10 and the feeding channel 11, the to-be-evaporated material does not fall into the crucible through the hole 10 in advance in material distribution to cause non-uniform material distribution. Optionally, handle 33 may further be provided on the top plate 31, so as to place and take out the barrier 3 conveniently.

According to the specific implementation of the present disclosure, the slider 15 is pulled and pushed through the adjusting threaded rod 18. When the slider is pulled, the to-be-evaporated material is placed into the feeding channel 11. The to-be-evaporated material is pushed into the hole 10 by pushing the slider 15 and then guided to the crucible through the guide tube 12. In addition, the slider 15 is located through the hollow locating rod 16, such that the slider 15 in the feeding channel 11 is located at a same position to quantify the to-be-evaporated material.

According to the specific implementation of the present disclosure, the baffle plate 19 shields the feeding channel 11 between the slider 15 and the edge of the material distribution mechanism 1. In the material distribution, this can prevent the to-be-evaporated material (copper particles or aluminum particles) from falling into the feeding channel 11 between the slider 15 and the edge of the material distribution mechanism 1.

According to the specific implementation of the present disclosure, the housing 2 may be trumpet-shaped. This can prevent the to-be-evaporated material from scattering to the ground in the material distribution to waste the material and cause environmental pollution.

It should be understood that in the description of the present disclosure, terms such as “first” and “second” are used merely for a descriptive purpose, and should not be construed as indicating or implying relative importance, or implicitly indicating a quantity of indicated technical features. Thus, features defined with “first” and “second” may explicitly or implicitly include one or more of the features. In the description of the present disclosure, “a plurality of” means two or more, unless otherwise specifically defined.

In the present disclosure, unless otherwise clearly specified, the terms such as “mounting”, “interconnection”, “connection” and “fixation” are intended to be understood in a broad sense. For example, the “connection” may be a fixed connection, removable connection or integral connection; may be a mechanical connection or electrical connection; may be a direct connection or indirect connection using a medium; and may be a communication or interaction between two elements. Those of ordinary skill in the art may understand specific meanings of the above terms in the present disclosure based on a specific situation.

In the present disclosure, unless otherwise explicitly specified, when it is described that a first feature is “above” or “below” a second feature, it indicates that the first and second features are in direct contact or the first and second features are in indirect contact through an intermediate feature. In addition, when it is described that the first feature is “over”, “above” and “on” the second feature, it indicates that the first feature is directly or obliquely above the second feature, or simply indicates that an altitude of the first feature is higher than that of the second feature. When it is described that a first feature is “under”, “below” or “beneath” a second feature, it indicates that the first feature is directly or obliquely under the second feature or simply indicates that the first feature is lower than the second feature.

In the description of this specification, the description with reference to the terms such as “one embodiment”, “some embodiments”, “example”, “specific example” or “some examples” means that specific features, structures, materials or characteristics described in connection with the embodiment or example are included in at least one embodiment or example of the present disclosure. In this specification, the schematic expression of the above terms is not necessarily directed to the same embodiment or example. Moreover, the specific features, structures, materials, or characteristics described may be combined in a suitable manner in any one or more embodiments or examples. In addition, those skilled in the art may combine different embodiments or examples described in this specification and characteristics of the different embodiments or examples without mutual contradiction.

Although the embodiments of the present disclosure are illustrated above, it should be understood that the above embodiments are merely illustrative and may not be construed as limiting the scope of the present disclosure. Changes, modifications, substitutions and variations may be made to the above embodiments by a person of ordinary skill in the art within the scope of the present disclosure.

What is claimed is:

1. An evaporation material distributor, comprising:
a material distribution mechanism and a housing, wherein the material distribution mechanism is provided at a bottom of the housing; and
the material distribution mechanism comprises a plurality of through holes formed inside the material distribution mechanism at intervals along a length direction of the material distribution mechanism; and
a plurality of feeding channels respectively provided at two sides of the material distribution mechanism, and corresponding to the plurality of through holes, wherein each of the plurality of feeding channels communicates with a corresponding one of the plurality of through holes.

2. The evaporation material distributor according to claim 1, wherein
the plurality of through holes are formed in a middle of the material distribution mechanism in two rows.

3. The evaporation material distributor according to claim 1, wherein
the material distribution mechanism further comprises a plurality of guide tubes respectively provided at bottoms of the plurality of through holes.

4. The evaporation material distributor according to claim 3, wherein
the material distribution mechanism further comprises a plurality of locating tubes; and the plurality of locating tubes are respectively sleeved on inner sidewalls of the plurality of guide tubes; and
each of the plurality of locating tubes is longer than each of the plurality of guide tubes; and each of the plurality of locating tubes comprises a first end connected to the through hole, and a second end communicating with a crucible.

5. The evaporation material distributor according to claim 1, wherein
gaps are respectively provided at tangents between the plurality of through holes and the plurality of feeding channels;
the evaporation material distributor further comprises a barrier, the barrier comprises a top plate and barrier plates, the barrier plates are vertically connected to the top plate, and the barrier plates are respectively inserted into the gaps; and
a width of each of the barrier plates is the same as a depth of each of the plurality of feeding channels.

6. The evaporation material distributor according to claim 5, wherein
a handle is provided on the top plate.

7. The evaporation material distributor according to claim 1, wherein
the material distribution mechanism further comprises a slider provided in each of the plurality of feeding channels;
a hollow locating rod threadedly connected to a sidewall of the material distribution mechanism through a bolt, and corresponding to each of the plurality of feeding channels; and
an adjusting threaded rod fixedly connected to the slider through the hollow locating rod.

8. The evaporation material distributor according to claim 7, wherein
the material distribution mechanism further comprises a baffle plate provided on each of the plurality of feeding channels; and an edge of a side of the baffle plate adjacent to the through hole is fixedly connected to the slider.

9. The evaporation material distributor according to claim 1, wherein
the housing is trumpet-shaped.

10. A vacuum evaporation device, comprising the evaporation material distributor according to claim 1.

11. The evaporation material distributor according to claim 2, wherein
the material distribution mechanism further comprises a plurality of guide tubes respectively provided at bottoms of the plurality of through holes.

12. The evaporation material distributor according to claim 2, wherein
gaps are respectively provided at tangents between the plurality of through holes and the plurality of feeding channels;
the evaporation material distributor further comprises a barrier, the barrier comprises a top plate and barrier plates, the barrier plates are vertically connected to the top plate, and the barrier plates are respectively inserted into the gaps; and
a width of each of the barrier plates is the same as a depth of each of the plurality of feeding channels.

13. The vacuum evaporation device according to claim 10, wherein in the evaporation material distributor, the plurality of through holes are formed in a middle of the material distribution mechanism in two rows.

14. The vacuum evaporation device according to claim 10, wherein in the evaporation material distributor, the material distribution mechanism further comprises a plurality of guide tubes respectively provided at bottoms of the plurality of through holes.

15. The vacuum evaporation device according to claim 14, wherein in the evaporation material distributor, the material distribution mechanism further comprises a plurality of locating tubes; and the plurality of locating tubes are respectively sleeved on inner sidewalls of the plurality of guide tubes; and
each of the plurality of locating tubes is longer than each of the plurality of guide tubes; and each of the plurality of locating tubes comprises a first end connected to the through hole, and a second end communicating with a crucible.

16. The vacuum evaporation device according to claim 10, wherein in the evaporation material distributor, gaps are respectively provided at tangents between the plurality of through holes and the plurality of feeding channels;
the evaporation material distributor further comprises a barrier, the barrier comprises a top plate and barrier plates, the barrier plates are vertically connected to the top plate, and the barrier plates are respectively inserted into the gaps; and
a width of each of the barrier plates is the same as a depth of each of the plurality of feeding channels.

17. The vacuum evaporation device according to claim 16, wherein in the evaporation material distributor, a handle is provided on the top plate.

18. The vacuum evaporation device according to claim 10, wherein in the evaporation material distributor, the material distribution mechanism further comprises a slider provided in each of the plurality of feeding channels;
a hollow locating rod threadedly connected to a sidewall of the material distribution mechanism through a bolt, and corresponding to each of the plurality of feeding channels; and
an adjusting threaded rod fixedly connected to the slider through the hollow locating rod.

19. The vacuum evaporation device according to claim 18, wherein in the evaporation material distributor, the material distribution mechanism further comprises a baffle plate provided on each of the plurality of feeding channels; and an edge of a side of the baffle plate adjacent to the through hole is fixedly connected to the slider.

20. The vacuum evaporation device according to claim 10, wherein in the evaporation material distributor, the housing is trumpet-shaped.
